(19) United States
(12) Patent Application Publication
(10) Pub. No.: US 2009/0322351 A1
(43) Pub. Date: Dec. 31, 2009

(54) Adaptive Capacitive Sensing

(76) Inventor: Scott C. McLeod, Oro Valley, AZ (US)

Correspondence Address: MEYERTONS, HOOD, KIVLIN, KOWERT & GOETZEL, P.C., P.O. BOX 398, AUSTIN, TX, 78767-0398, US

(21) Appl. No.: 12/367,336

(22) Filed: Feb. 6, 2009

Related U.S. Application Data
(60) Provisional application No. 61/076,482, filed on Jun. 27, 2008.

(51) Int. Cl. G01R 27/26; G06F 15/00; G06F 3/045

(52) U.S. Cl. 324/658; 702/189; 345/174

(57) ABSTRACT

A capacitive sensing circuit may comprise an RC (resistive-capacitive) bridge circuit, with a switching signal simultaneously applied to a reference path, and a signal path comprising the capacitance to be detected. Small perturbations in the capacitance may be detected by mixing/correlating a difference signal representative of the difference between the reference path signal and the signal path signal, to the switching signal. The output of the mixer may be filtered to virtually eliminate all EMI signals. A narrowband approach may also allow filtering of unwanted signals, enabling operation in systems susceptible to high levels of noise. Frequency stepping of the switching signal may minimize inband signal interference, and allow operation in the presence of many signals that would otherwise result in failure of the sensing circuit. Pad calibration may be implemented to free the user from a need to characterize each button channel capacitance and tailor the operation for each channel.

### PRIORITY CLAIM

This application is a continuation-in-part of U.S. Provisional Application Ser. No. 61/076,482 titled “Adaptive Capacitive Sensing” filed Jun. 27, 2008, whose inventor was Scott C. McLeod, and which is hereby incorporated by reference in its entirety as though fully and completely set forth herein.

### BACKGROUND OF THE INVENTION

1. Field of the Invention

This invention relates generally to the field of semiconductor circuit design, and more particularly to the design of an adaptive capacitive sensing circuit.

2. Description of the Related Art

It's been a high priority for many electronics manufacturers to offer user interfaces that are powerful yet simple to use, while remaining highly reliable. Some of the more popular interfaces have been touchscreens and touchpads. Touchscreens and touchpads can typically detect the location of touches within the display/pad area, allowing the display/pad to be used as an input device, and in the case of touchscreens, making it possible for the user to directly interact with the display's content. Such displays/pads can be attached to computers, and have become more and more prevalent in recent personal digital assistants (PDAs), laptop computers, and satellite navigation and mobile phone devices, making these devices more user-friendly and effective.

Many touchscreens/touchpads are designed based on capacitive sensing principles. Such touchscreens/touchpads may feature a panel coated with a material that conducts a continuous electrical current across the sensor, which exhibits a precisely controlled field of stored electrons in both the horizontal and vertical axes to achieve capacitance. When the sensor's normal capacitive field (considered its reference state) is altered by another capacitive field, for example someone's finger, electronic circuits measure the resultant distortion in the characteristics of the reference field, and send the information about the event to a controller for processing. Capacitive sensors can either be touched with a bare finger or with a conductive device being held by a bare hand.

With the growing variety of capacitive-sensing ICs (Integrated Circuits) on the marketplace, even custom designs have become more affordable. Capacitive-sensor ICs from many manufacturers, such as Analog Devices, Cypress Semiconductor, Freescale Semiconductor, and Quantum Research Group, represent different approaches to capacitive sensing, with varying degrees of reliability in determining key-press information across a range of user profiles and environments. Mobile devices configured with touch sensors especially present significant challenges, due to highly variable environmental conditions to which they may be subjected. For example, at one time the mobile device may be in free space, while at another time it may be situated next to a PC, cell phone, or other electronic equipment that emits unpredictable frequency components at various field strengths. Electrostatic discharge is another potential cause for capacitive sensors mistriggering or not functioning properly, and water and other contaminants can cause similar problems. To overcome these and other issues, such as drift with temperature and time, touch-sensor ICs sometimes embed logic and analog subsystems that continually calibrate the system. By characterizing individual channels, such techniques can also accommodate keypads that have widely different user fingerprints and key profiles, improving both detection and the product designer's options.

To safeguard against false triggering due to momentary unintentional touches, an object's proximity, EMI (electromagnetic interference), or ESD (electrostatic discharge) events, some circuits have implemented voting filters that require the system to detect a number of successful samples before registering a touch. Some circuits feature signal-processing logic implementing adjacent-key suppression, an iterative technique that repeatedly measures each key's signal strength to determine the user's true selection by identifying the area of greatest signal-level change. Providing that the selected key's signal remains above a threshold level, the sensor then ignores adjacent keys. Some chips also implement automatic drift-compensation schemes, which are in most cases sufficiently responsive to maintain detection performance in applications such as microwave-oven panels that can experience relatively substantial temperature slew rates. An algorithm may periodically assess each input's baseline-signal level when no one is touching the sensor, adjusting the detection threshold to maintain constant sensitivity. Designers can set the threshold level using a variety of techniques.

In many capacitive sensing circuits, both noise and detection thresholds may be set, enabling continual software correction for systems that experience frequent environmental changes, and there are efforts to devise methods for temperature compensation to maintain the current source's accuracy in circuits that use a constant-current-source approach. However, one weakness of today's products remains their susceptibility of the sensor to coupling unwanted large electromagnetic signals onto the [touch] pad, which typically corrupts the sensor output such that false touches are reported, or, in other words, resulting in false triggering of the touch pad. The amount of coupling is largely due to the circuit impedance of the pad and what is connected to the pad. Some capacitive sensing circuits use relaxation oscillators, where the frequency defining capacitance of the oscillator is the capacitance being detected. Other charge transfer methods have also been used to determine capacitance. Most of these solutions, however, have difficulty insuring proper operation in the presence of a high EMI environment, and false detections have caused problems in many PC applications. There is therefore a need to reliably sense very small changes in capacitance in a high EMI environment without false detections or the sensor going blind (i.e. not detecting any capacitance changes).

Many other problems and disadvantages of the prior art will become apparent to one skilled in the art after comparing such prior art with the present invention as described herein.

### SUMMARY OF THE INVENTION

A capacitive sensing circuit may comprise a resistive-capacitive bridge circuit with a signal path and a reference path, with the signal path configured to connect to the capacitance to be detected. A switching signal may simultaneously be applied to the signal path and the reference path, and a difference signal representative of a difference between the reference path signal and the signal path signal may be obtained. Small perturbations in the capacitance may be detected by mixing/correlating the difference signal to the switching signal. It should be noted that as described herein, correlation is performed by mixing two signals, where the output generated by the mixing operation is indicative of the level of correlation between the two signals. The output of the mixer/correlator may be filtered using narrowband low-pass filters to virtually eliminate all EMI signals. Since the narrowband approach allows filtering out unwanted signals, it enables operation in systems that are susceptible to high levels of noise. The bridge circuit may also provide low impedance at the button node to minimize EMI susceptibility. Frequency stepping the switching signal with specified frequency increments may minimize in-band signal interference, and allow operation in the presence of many signals that would otherwise result in failure of the sensing circuit. Pad calibration may also be implemented to free the user from a need to characterize each button channel capacitance and tailor the operation for each channel.

A sensing apparatus may comprise an interface device (which may be a button pad) with a specific electrical characteristic (which may be parasitic capacitance), a sensing signal-path that includes the interface device, a reference signal-path, and a mixer. The sensing signal-path may be configured to be driven by a control signal, which may be a periodic signal having a specific frequency to obtain an input signal. The reference signal-path may be configured to be driven by the control signal to obtain a reference signal. The mixer may be configured to generate a difference signal representative of a difference of the input signal and the reference signal, and correlate the difference signal to the control signal to obtain an output signal, with the output signal indicative of a change in the specific electrical characteristic of the interface device.

In one set of embodiments, a method may comprise generating an input signal by driving a signal sensing-path with a switching signal having a specific frequency, where the signal sensing-path comprises an interface device having a specific electrical characteristic. The method may further include generating a reference signal by driving a reference sensing-path with the control signal, generating a difference signal representative of a difference of the input signal and the reference signal, and generating an output signal by correlating the difference signal to the control signal, where the output signal is indicative of a change in the specific electrical characteristic of the interface device.

An RC bridge-circuit may be configured to perform capacitive sensing using correlation. A sensing signal-path may comprise a first resistor configured to couple to a button pad having a parasitic capacitance that changes when an object is brought within at least a specified distance of the button pad. A reference signal-path may comprise a reference resistor coupled to a reference capacitor. An oscillator may be configured to generate a switching signal having a specific frequency, and apply the switching signal to the sensing signal-path to obtain an input signal, and to the reference signal-path to obtain a reference signal. The oscillator may also provide the switching signal to a mixer. The mixer may be configured to generate a difference signal representative of a difference of the input signal and the reference signal, and correlate the difference signal to the switching signal to obtain an output signal. The output signal will be indicative of a change in the parasitic capacitance of the button pad. A data converter may convert an amplified version of the output signal to a numeric value. When a difference between successively obtained numeric values exceeds a specified value, a flag may be set to indicate that an object has been detected in the proximity of the button pad.

Other aspects of the present invention will become apparent with reference to the drawings and detailed description of the drawings that follow.

### BRIEF DESCRIPTION OF THE DRAWINGS

The foregoing, as well as other objects, features, and advantages of this invention may be more completely understood by reference to the following detailed description when read together with the accompanying drawings in which:

FIG. 1 is a diagram illustrating a capacitive sensing pad according to principles of prior art;

FIG. 2 is a diagram illustrating a bridge-type capacitive sensing circuit configured according to principles of prior art;

FIG. 3 is a diagram illustrating how an EMI source affects sensor circuitry, according to principles of prior art;

FIG. 4 is a circuit diagram of a capacitive sensing circuit configured with a relaxation oscillator, according to principles of prior art;

FIG. 5 is a diagram of one embodiment of a capacitive sensor apparatus, according to principles of the present invention;

FIG. 6 shows waveforms indicating the behavior of select signals from the apparatus of FIG. 5;

FIG. 7 shows a bridge-type capacitive sensing circuit configuration according to one embodiment of the present invention;

FIG. 8 shows one possible embodiment of the band-pass filters used in the apparatus of FIG. 5;

FIG. 9 shows one embodiment of the mixer from FIG. 5 configured with a zero degree phase correlator/mixer element and a quadrature correlator mixer element;

FIG. 10 shows one embodiment of a voltage to frequency converter circuit used as the data converter in the apparatus of FIG. 5;

FIG. 11 shows waveforms indicating the behavior of select signals from the voltage to frequency converter circuit of FIG. 10;

FIG. 12 shows a transistor diagram of a section of one possible implementation of the apparatus of FIG. 5; and

FIG. 13 shows a table with example values of the contribution of the amplitude difference component at the output of the correlator/mixer element, and the phase difference component at the output.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must).” The term “include”, and derivations thereof, mean “including, but not limited to”. The term “connected” means “directly or indirectly connected”, and the term “coupled” means “directly or indirectly connected”.

### DETAILED DESCRIPTION OF THE PREFERRED EMBODIMENTS

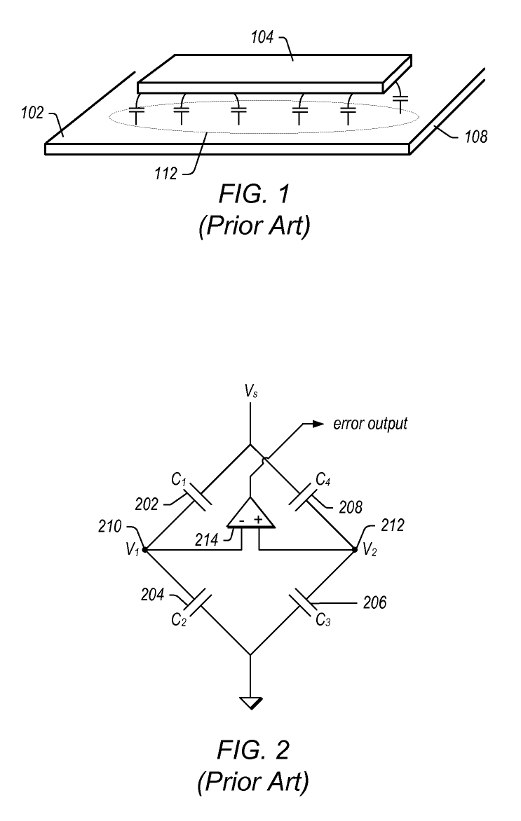

Various embodiments of the present invention comprise a capacitive sensing system capable of detecting an increase in capacitance on a pad that may occur when an object, such as a fingertip is near the pad or touches the pad. It should be noted that in many embodiments, the actual surface of the pad may be covered with an insulating layer, in which case the insulating layer may be considered a part of the pad, and touching the pad may be interpreted as touching the insulating layer. As shown in FIG. 1, a metal pad 104 may be configured on circuit board 102 comprising a ground layer 108. The capacitance between metal pad 104 and the ground layer 108 is illustrated by capacitance 112.l Placing an object, such as a human finger near or on pad 104 may result in added capacitance between pad 104 and ground, thereby increasing the pad capacitance. Typical parasitic pad capacitance (i.e. capacitance 112) may range from 5 pF to 50 pF, while typical capacitance increase from a human finger may be in the 100 fF to 2 pF range. In some embodiments, the proximity of an object, e.g. a finger, to pad 104 may also be detected even when the object/finger is some distance away from pad 104. This may lead to a requirement of detecting capacitance changes of less than 100 fF (100 femto Farads).

One type of capacitive sensing apparatus or system includes a bridge type circuit for detecting a small change in component value, as shown in FIG. 2. The circuit shown in FIG. 2 may comprise four capacitors (C₁-C₄; 202-208) arranged in a closed-loop series as shown, with a supply voltage V_{S} applied to the common node of C₁ 202 and C₄ 208, and the common node of C₂ 204 and C₃ 206 tied to a common reference, such as ground. When the ratio of C₁/C₂ is equal to the ratio of C₄/C₃, the voltage V₁ at node 210 will be equal to the voltage V₂ at node 212, hence the error output produced by comparator 214, which may be a differential error amplifier, will be zero. When a difference capacitance ΔC is added to C₄, the voltages will change as follows:

$${V}_{1} = {V}_{S} \frac{\frac{1}{{C}_{2}}}{\frac{1}{{C}_{1}} + \frac{1}{{C}_{2}}} = {V}_{S} \frac{\frac{1}{{C}_{2}}}{\frac{{C}_{1} + {C}_{2}}{{C}_{1} {C}_{2}}} = \frac{{C}_{1}}{{C}_{1} + {C}_{2}} \cdot {V}_{S} \qquad ( 1 )$$

In one set of embodiments, for the sake of simplicity, C₄ may be set to the same value as C₁, and C₃ may be set to the same value as C₂. V2 may then be calculated as:

$${V}_{2} = \frac{{C}_{1} + Δ C}{{C}_{2} + {C}_{1} + Δ C} \cdot {V}_{S} , \qquad ( 2 )$$

which may be reduced to approximately

$$\frac{{C}_{1} + Δ C}{{C}_{2} + {C}_{1}} , if Δ C ≪ {C}_{2} + {C}_{1} . \qquad ( 3 )$$

The following relationship may then be obtained:

$${V}_{2} - {V}_{1} = {V}_{S} ( \frac{{C}_{1} + Δ C}{{C}_{2} + {C}_{1}} - \frac{{C}_{1}}{{C}_{2} + {C}_{1}} ) = {V}_{S} ( \frac{Δ C}{{C}_{2} + {C}_{1}} ) . \qquad ( 4 )$$

As indicated by the equations above, a difference in capacitance may result in a small voltage difference between V₁ and V₂, which may be gained up by error amplifier 214 to provide a linear error output vs. ΔC.

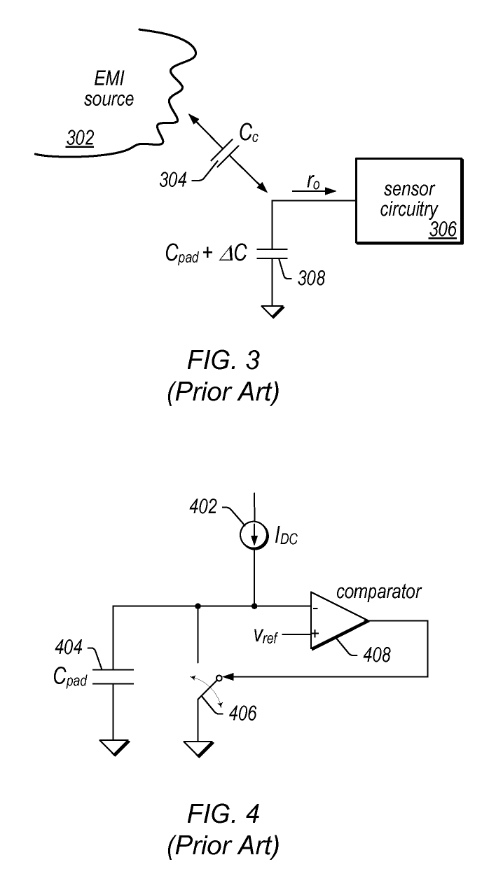

As previously mentioned, one weakness in systems that employ a circuit such as the bridge circuit shown in FIG. 2 is the susceptibility of the sensor to large electromagnetic coupling of unwanted signals onto the pad, which corrupts the sensor output such that false touches are reported. The amount of coupling is typically due to the circuit impedance of the pad and what connects to it. FIG. 3 illustrates how an EMI source 302, which may be digital switching noise from a computer motherboard or the large spikes caused by an on-board switching power supply, may affect sensor circuitry 306. Additional EMI sources may include LCD backlighting signals that may switch at rates of 50 kHz to 200 kHz and may have amplitudes of ˜1 kV. Cell phones may also couple high frequency signals onto the pad.

If coupling capacitance C_{c} 304 is on the order of 50 fF and pad capacitance C_{pad} 308 is 25 pF, then the coupling of a 100 kHz backlighting signal at 1 kV onto the pad would be:

$${Vpad}_{EMI} = \frac{50 fF}{25 pf + 50 fF} \cdot 1 kV = 2 V , \qquad ( 5 )$$

which may be the coupled voltage if r₀=∞. If the pad impedance included r₀ then the coupled signal would decrease. For example, setting r₀ to 7 kΩ, equation 5 may be rewritten as:

$${Vpad}_{EMI} = \frac{{r}_{o} \vert \vert {X}_{25 pF}}{{r}_{o} \vert \vert {X}_{25 pF} + {X}_{50 fF}} \cdot 1 kV , \qquad ( 6 )$$

where

$${X}_{25 pF} = \frac{1}{j2π f 25 pF } ,$$

and the value off is set to 100 kHz, and, where

$${X}_{50 pF} = \frac{1}{j2π f 50 fF } ,$$

leading to:

$${Vpad}_{EMI} ≅ \frac{7 k Ω}{- j32 M Ω} \cdot 1 kV = j0 .219 V or 219 mV @ 90 ° \qquad ( 7 )$$

The lower pad impedance may reduce the susceptibility to EMI by an order of magnitude, as shown below:

$$\frac{0.219}{2 V} = 0.11 . \qquad ( 8 )$$

Many present-day implementations use a relaxation oscillator. FIG. 4 shows one example of such an implementation, with DC current source 402 and comparator 408, in which the pad impedance is set by C_{pad} 404 only, and is therefore very susceptible to EMI signals. The comparator's inverting input may be coupled to ground via switch 406. Another weakness of this method lies in the fact that any signal near the relaxation oscillator's frequency of oscillation can cause the oscillator to lock onto the interfering EMI signal, and once locked, the sensor may not detect capacitance changes on the pad.

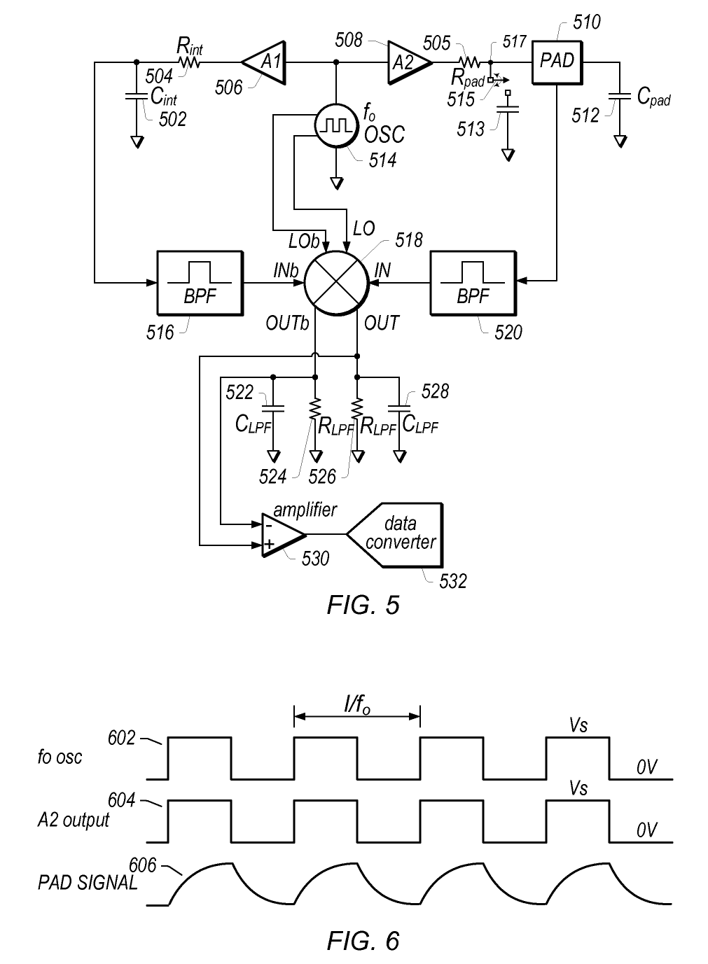

FIG. 5 shows a block diagram of an apparatus designed according to one embodiment of the present invention to perform capacitive sensing. The apparatus may comprise an RC (resistive-capacitive) bridge circuit, with a switching signal simultaneously applied to a signal-path comprising the capacitance to be detected, and a reference signal-path. Small perturbations in the capacitance in the signal-path may be detected by mixing/correlating a difference signal obtained from the reference path signal and the pad signal-path signal to the switching signal, and may be filtered such that virtually all EMI signals are eliminated, to achieve high resolution. The bridge circuit may be configured to provide low impedance at the button node to minimize EMI susceptibility. A narrowband approach may allow filtering out unwanted signals, thus enabling operation in systems that are susceptible to high levels of noise. Frequency stepping of the switching signal may minimize in-band signal interference, and allow operation in the presence of many signals that would otherwise result in failure of the sensing circuit. Automatic pad calibration may also be implemented to free the user from a need to characterize each button channel capacitance and tailor the operation for each channel.

Various components and elements comprised in the apparatus shown in FIG. 5 will now be described.

As shown in FIG. 5, A1 506 and A2 508 may be buffers with drive strength appropriate to the load that each buffer may drive. The load for buffer 508 may comprise a resistance R_{pad} 505 in series with pad capacitance C_{pad} 512, coupled to a reference voltage, such as signal ground, for example. R_{pad} 505 may be a resistance internal to the sensing apparatus, and C_{pad} 512 may represent an electrical characteristic of PAD 510, more specifically parasitic pad capacitance. Referring again to FIG. 1, PAD 510 in FIG. 5 may correspond to metal pad 104 in FIG. 1, and capacitance 512 in FIG. 5 may correspond to parasitic capacitance 112 formed on circuit board 102. Thus, PAD 510 may comprise the metal structure shown in FIG. 1. The load for buffer 506 may comprise internal (to the sensing apparatus) resistance Rᵢₙₜ 504 in series with internal (to the sensing apparatus) capacitance Cᵢₙₜ 502 coupled to ground. The respective values of resistor 504 and capacitor 502 (more specifically, their RC time constant) may nominally be set to the middle of the range of the expected RC value defined by internal resistor 505 and parasitic capacitance 512. Resistor 505 may then be adjusted in a calibration mode such that the two time constants defined respectively by resistor 504/capacitor 502 and resistor 505/capacitance 512 are virtually equal. Possible calibration methods that may be used with the sensing apparatus of FIG. 5 will be further discussed below.

OSC 514 may be an oscillator with a 50% duty cycle, preferably at frequency f₀ that may drive buffers 506 and 508. Oscillator 514 may also provide a signal LO to correlator/mixer element 518. LO may have a phase identical to the phase of the signals applied to buffers 506 and 508. Oscillator 514 may also provide the complement of LO (i.e. 180° out of phase) to correlator/mixer element 518. In a more sophisticated implementation, oscillator 514 may also be configured to provide quadrature (−90° and −270°) signals to the correlator/mixer element, and may be stepped in frequency to minimize the effect of EMI signals on the pad. In one set of embodiments, R_{pad} 505 and C_{pad} 512 may form a simple RC filter for the output signal of buffer 508 to Pad 510, resulting in the pad signal as shown in the timing/signal diagram shown in FIG. 6.

Preferably, the pole formed by R_{pad} 505 and C_{pad} 512 may be at frequency f₀ as defined in (9). When operating with this condition, the largest amplitude and phase changes may be obtained with only small changes in C_{pad}.

$$Rpad \cdot Cpad = \frac{1}{2 π {f}_{0}} . \qquad ( 9 )$$

The PAD signal at frequency f₀ may have harmonies at 3f₀, 5f₀, etc., but the largest component may be at the fundamental frequency f₀, which may be shifted by −45° when the condition of equation 9 is met. The amplitude and phase of the fundamental frequency may be expressed as follows:

$$\begin{matrix}PADSIGNAL = {V}_{S} \frac{1 / j2π {f}_{0} {C}_{pad}}{{R}_{pad} + 1 / j2π {f}_{0} {f}_{pad}} \\ = {V}_{S} \frac{1}{1 + j {R}_{pad} {C}_{pad} 2 π {f}_{0}} ,\end{matrix} \qquad ( 10 )$$

where VS is the supply voltage applied to A2 508. By applying the time constant as expressed in equation 9, equation 10 may be rewritten as:

$$\begin{matrix}PADSIGNAL = {V}_{S} \cdot \frac{1}{1 + j} \\ = \frac{1}{\sqrt{2}} {V}_{S} ∠ - {tan}^{- 1} 1 \\ = \frac{1}{\sqrt{2}} {V}_{S} ∠ - 45 ° .\end{matrix} \qquad ( 11 )$$

A change in the amplitude and phase with a small ΔC change in C_{pad} 512, which may result from a finger touch, for example, may be calculated as follows:

$${C}_{pad}^{′} = {C}_{pad} + Δ {C}^{′} = {C}_{pad} ( 1 + \frac{Δ {C}^{′}}{{C}_{pad}} ) . \qquad ( 12 )$$

### If

$$\frac{Δ {C}^{′}}{Cpad} = Δ , \qquad equation 11$$

may be rewritten as:

$$PADSIGNAL = {V}_{S} \cdot \frac{1}{1 + j ( 1 + Δ )} ∠ - {tan}^{- 1} ( 1 + Δ ) . \qquad ( 13 )$$

Rᵢₙₜ 504 and Cᵢₙₜ 502 may form a simple RC filter similar to the RC filter formed by R_{pad} 505 and C_{pad} 512. Preferably, the pole formed by Rᵢₙₜ 504 and Cᵢₙₜ 502 will be the same value as the pole formed by R_{pad} 505 and C_{pad} 512, leading to:

$${R}_{int} \cdot {C}_{int} = \frac{1}{2 π {f}_{0}} . \qquad ( 14 )$$

Therefore, the signal at the reference path may be expressed as:

$$R E F signal = \frac{1}{\sqrt{2}} \cdot {V}_{S} {∠tan}^{- 1} 1 = \frac{1}{\sqrt{2}} {V}_{S} ∠ - 45 ° . \qquad ( 15 )$$

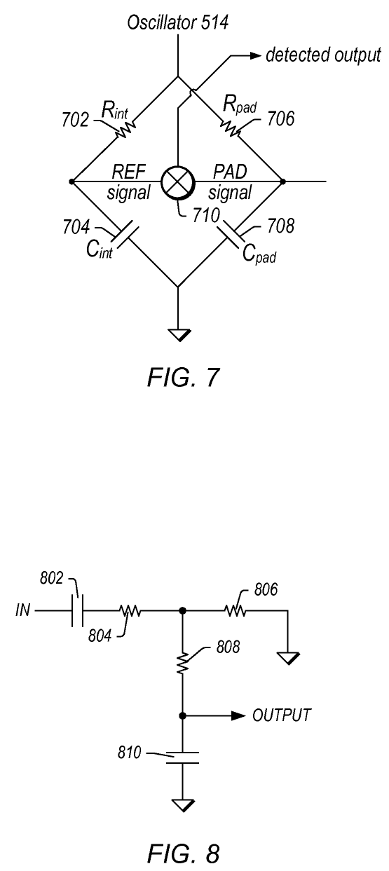

With these two paths and signals, a bridge network may be formed as shown in FIG. 7.

The circuit of FIG. 7 illustrates the bridge network that may be formed by resistances 702 and 706, corresponding to internal resistance 504 and internal resistance 505, respectively, from FIG. 5, and capacitors 704 and 708, corresponding to internal capacitor 502 and (parasitic) pad capacitance 512, respectively, also from FIG. 5. Correlator/mixer element 710—corresponding to correlator/mixer element 518 from FIG. 5—may be used to obtain a difference signal from a reference signal (REF signal corresponding to INb from FIG. 5) and a pad signal (PAD signal corresponding to IN from FIG. 5), and correlate the difference signal to a local oscillator (e.g. oscillator 514 from FIG. 5—not shown in FIG. 7) to produce a detected output (corresponding to OUTb and OUT from FIG. 5).

The band-pass filters (BPF) 516 and 520 shown in FIG. 5 may be identical in both paths. Each BPF (516 and 520) may be composed of a high-pass filter (HPF) in series with a low-pass filter (LPF) such that the total phase shift at frequency f₀ through the filter is +45°, the high pass filter may have a +67.5° phase shift at frequency f₀, and the low pass filter may have a −22.5° phase shift at frequency f₀. These phase values are provided here by way of example to present preferred embodiments, but various other embodiments may feature different phase shift values as desired. BPFs 516 and 520 may also be configured to attenuate their respective input signals such that the respective output signal levels of BPFs 516 and 520 are within the dynamic range of the input of correlator/mixer element 518. One possible BPF implementation is shown in FIG. 8. In this implementation, the BPF may comprise an HPF (capacitor 802 and resistors 804, 806) coupled in series with an LPF (capacitor 810 and resistor 808) as shown, to produce an output (OUTPUT) based on an input (IN).

Correlator/mixer element 518 may be a differential mixer/correlator configured to multiply the difference of IN and INb with the signals (LO and LOb) from oscillator 514. From the output of buffer 508, the fundamental frequency at f₀ may be shifted in phase −45° to PAD 510, and the fundamental frequency may be shifted by +45° from PAD 510 through BPF 520, resulting in a total phase shift from buffer 508 (and hence the output of oscillator 514) to the input (IN) of correlator/mixer element 518 of −45°+45°=0°. This relationship may also hold true of the alternative path from oscillator 514 through buffer 506 and BPF 516 to correlator/mixer element 518 input (INb), resulting in an overall phase shift 0° in that path as well.

If there is no difference in the two inputs IN and INb—for example, if there is no ΔC from a finger touch—then the difference of IN and INb may be zero into correlator/mixer element 518, producing a zero output signal. If there is a disturbance, e.g. a finger touch, on PAD 510, and hence a ΔC difference in the overall parasitic capacitance 512, the signal in the signal-path of PAD 510 (through buffer 508) may change with respect to the signal in the reference signal-path (through buffer 506), and may have two separate components, an amplitude difference induced signal, and a phase difference induced signal.

The amplitude induced signal may be characterized as follows:

A cos(2πf₀ₜ+θ)−A′cos(2πf₀ₜ+θ)=(A−A′) cos(2πf₀ₜ+θ), (16)

where:

$$\begin{matrix}A = \frac{{V}_{S}}{\sqrt{1 + 1}} = \frac{{V}_{S}}{\sqrt{2}} , & ( 17 ) \\ {A}^{′} = \frac{{V}_{S}}{\sqrt{1 + {( 1 + Δ )}^{2}}} , & ( 18 )\end{matrix}$$

and

(1+Δ)²=1+2Δ+Δ²≈1+2Δ if Δ<<1, (19)

leading to:

$${A}^{′} = \frac{{V}_{S}}{\sqrt{2 + 2 Δ}} = \frac{{V}_{S}}{\sqrt{2} \cdot \sqrt{1 + Δ}} . \qquad ( 20 )$$

Subtracting A′ from A:

$$A - {A}^{′} = {V}_{S} ( \frac{1}{\sqrt{2}} - \frac{1}{\sqrt{2} \cdot \sqrt{1 + Δ}} ) = \frac{{V}_{S}}{\sqrt{2}} ( 1 - \frac{1}{\sqrt{1 + Δ}} ) , \qquad ( 21 )$$

leading to:

$$A - {A}^{′} = \frac{{V}_{S}}{\sqrt{2}} ( \frac{\sqrt{1 + Δ} - 1}{\sqrt{1 + Δ}} ) \approx \frac{{V}_{S}}{\sqrt{2}} ( \sqrt{1 + Δ} - 1 ) . \qquad ( 22 )$$

therefore combining (16) and (22):

$$A cos ( 2 π {f}_{0} t + θ ) - {A}^{′} cos ( 2 π {f}_{0} t + θ ) = \frac{{V}_{S}}{\sqrt{2}} ( \sqrt{1 + Δ} - 1 ) cos ( 2 π {f}_{0} t + θ ) . \qquad ( 23 )$$

As indicated by the above equations, because there may be no signal phase shift for any amplitude difference induced signal (component), it may be preferable to correlate the difference signal with a 0° phase shift signal at frequency f₀, where the 0° phase shift is relative to the output of oscillator 514 to buffer 506 and buffer 508.

The phase induced signal (component) may be characterized as follows:

A cos(2πf₀ₜ+θ)−A cos(2πf₀ₜ+θ+←θ), (24)

where Δθ represents the phase shift due to ΔC from a disturbance to the PAD. The following equations may be used to further characterize the signal:

$$cos u - cos v = - 2 sin ( \frac{u + v}{2} ) sin ( \frac{u - v}{2} ) , \qquad ( 25 )$$

where

u=2πf₀t+θ, (26)

and

v=2πf₀t+θ+Δθ. (27)

Expression 24 may then be rewritten as:

A cos(2πf₀t+θ)−A cos(2πf₀t+θ+Δθ), (28)

resulting in:

$$- 2 A sin ( \frac{2 π {f}_{0} t + θ + 2 π {f}_{0} t + θ ++ Δθ}{2} ) sin ( \frac{2 π {f}_{0} t + θ - 2 π {f}_{0} t - θ - Δθ}{2} ) \qquad ( 29 )$$

which may be written as:

$$- 2 A sin ( 2 π {f}_{0} t + θ + \frac{- Δθ}{2} ) sin ( \frac{- Δ θ}{2} ) \qquad ( 30 )$$

### If

$$A = \frac{{V}_{S}}{\sqrt{2}} ,$$

expression 30 may/be rewritten as:

$$- \sqrt{2} {V}_{S} sin ( \frac{- Δθ}{2} ) sin ( 2 π {f}_{0} t + θ + \frac{Δθ}{2} ) . \qquad ( 31 )$$

If Δθ is very small then

$$sin ( \frac{- Δθ}{2} ) \approx - \frac{Δθ}{2} , \qquad ( 32 )$$

and

$$\begin{matrix}sin ( 2 π {f}_{0} t + θ + \frac{Δθ}{2} ) \approx sin ( 2 π {f}_{0} t + θ ) \\ = \frac{{V}_{S}}{\sqrt{2}} \cdot Δθ sin ( 2 π {f}_{0} t + θ ) ,\end{matrix} \qquad ( 33 )$$

where Δθ is in radians. Thus, when

Δθ=−(tan⁻¹1−tan⁻¹(1+Δ)) (and tan⁻¹1=π/4). (34)

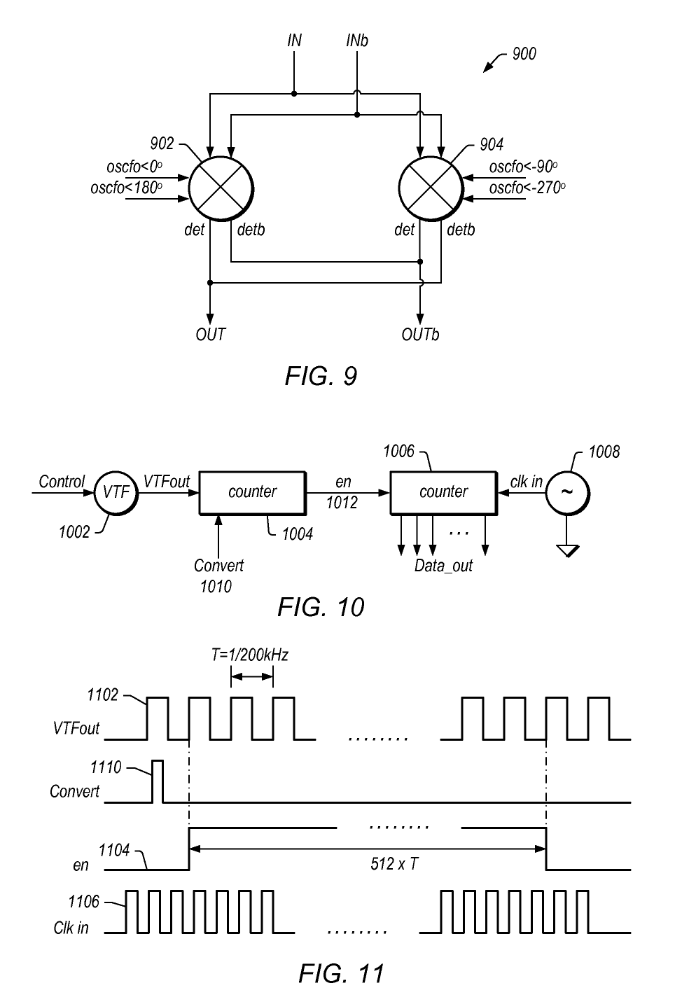

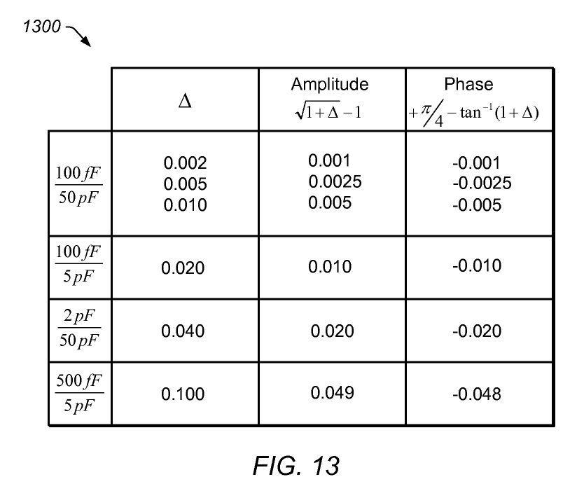

The table in FIG. 13 shows one example of the contribution of the amplitude difference component at the output of correlator/mixer element 518, and the phase component output. Because the phase induced A component is phase shifted by 90° (sine vs. cosine), to detect this component, a second correlator/mixer element may be added with a quadrature signal to correlate with the input signal difference (IN-INb). Thus, correlator/mixer 518 may therefore comprise two mixer elements. One example of such an arrangement is shown in FIG. 9, with a mixer/correlator 900 comprising correlator/mixer elements 902 and 904, where mixer/correlator element 902 may detect the amplitude difference induced signal component, and mixer/correlator element 904 may detect the phase induced signal component, as discussed above.

Referring again to FIG. 5, two low-pass filters (LPFs) coupled to the output of mixer/correlator 518 (OUT and OUTb, respectively) may be formed by R_{LPF} (524 and 526, respectively) and C_{LPF} (522 and 528, respectively), with the RC time constant of each LPF approximately equal to the conversion time of data converter 532. Overall, the RC time constant of each LPF may be determined such that the signal to noise ratio (SNR) of the output signal (OUT and OUTb) is optimized based on conversion time. For example, in some embodiments, if data converter 532 integrates the input (using for example an integrating ADC or ΔΣ ADC) for 2.5 ms, the optimal bandwidth of the LPF may be around 120.6 Hz. Gain amplifier 530 shown in FIG. 5 may provide gain to the output of correlator/mixer element 518 to match the dynamic range of data converter 532 (specifically, the dynamic range of the ADC, if data converter 532 is an ADC). Data converter 532 may be any integrating ADC, successive approximation register (SAR), or flash converter that would integrate over the specified conversion time period (2.5 ms in the discussed embodiment) or sample once at the end of the conversion time period (which, in this embodiment, may be 2.5 ms). Sampling times and sample numbers are given as examples and are not meant to limit various embodiments to the specific numbers provided. In some embodiments, data converter 532 may comprise a voltage to frequency (VTF) converter driven by amplifier 530. The output frequency would decrease as the amplifier output signal increased. The output signal of the VTF converter may be used to form an enable window to count a system clock.

One embodiment of a data converter based on an amplifier driving a voltage to frequency (VTF) converter is shown in FIG. 10, with the waveforms of selected corresponding signals shown in FIG. 11. As shown in FIG. 10, a control input (which may be obtained from the output of amplifier 530, for example) may be used by VTF 1002 to generate a frequency output VTFout, which may be provided to counter 1004. Counter 1004 may begin to count a specified number of pulses (e.g. 512 pulses) at the VTF output frequency VTFout (e.g. 200 kHz). Counter 1004 may also be configured to assert an enable signal (en) for the duration of the pulse count, upon convert signal 1010 being asserted, and provide the enable signal to counter 1006. Counter 1006 may be configured to count cycles of a system clock 1008 while the enable signal is asserted, and produce a result through the Data_out lines as shown. As VTF output frequency VTFout decreases (which may result from an object being brought into close proximity of pad 510, for example), the length of the enable pulse may increase, thus counter 1006 may count more cycles of the system clock 1008. The timing diagram in FIG. 11 shows examples of the waveforms for VTFout (waveform 1102), convert signal 1010 (waveform 1110), enable signal 1012 (waveform 1104), and clk in (waveform 1106) for the embodiment shown in FIG. 10. As previously mentioned, frequency and count values are provided as examples, and different embodiments may be designed based on different values as required by various system considerations.

To detect a touch where there is a change of capacitance, a ΔCount, or difference count between consecutive conversions on a given pad (e.g. PAD 510) would exceed a threshold count, and a flag may consequently be set to indicate a button (pad) touch. If the system gain was such that a given change in capacitance (e.g. a 2 pF ΔC) produced a specific percentage (e.g. −20%) shift in VTF frequency, then the delta count of consecutive no-touch to touch conversions may be:

ΔCount=Count_{Touch}−Count_{NoTouch}, (35)

where

$$\begin{matrix}{Count}_{Touch} = \frac{512}{( 1 - 0.2 ) \cdot 200 kHz} \cdot 10 MHz = 32 , 000 counts , \\ And & ( 36 ) \\ {Count}_{NoTouch} = \frac{512}{200 kHz} \cdot 10 MHz = 25 , 600 counts , & ( 37 )\end{matrix}$$

with

ΔCount=32,000−25,600=6,400 counts. (38)

For a 100 pF touch the number of counts would scale linearly

$$Δ Count = \frac{100 fF}{2 pF} \cdot 6 , 400 = 32 counts . \qquad ( 39 )$$

### Calibration

Referring again to FIG. 5, for performing calibration for different C_{pad} 512 capacitances, each button may have a value of capacitance that is not necessarily the same as other buttons but, as stated before, may be in a specified range, for example a range of 5 pF to 50 pF in certain embodiments. The two paths for the signal from oscillator 514 may be matched to each other and may have a specified phase shift, approximately −45° of phase shift in some preferred embodiments. Thus,

$${R}_{PAD} {C}_{PAD} = {R}_{INT} {C}_{INT} = \frac{1}{2 π {f}_{0}} . \qquad ( 39 )$$

This may be achieved by performing a calibration routine on each pad when there is only parasitic capacitance on the pad. In one set of embodiments, the value of internal resistor R_{pad} 505 may be stepped in value, or an internal capacitor may be connected to C_{pad} 512 (shown in FIG. 5 as capacitor 513, which may be switchably coupled to node 517, to couple capacitor 513 between node 517 and reference ground, as shown) to obtain a specified voltage value—which may be approximately 0V in certain preferred embodiments—at the output (OUT-OUTb) of correlator/mixer element 518. In one set of embodiments, a successive approximation routine may be used to perform the stepping of the value of R_{pad} 505 as efficiently as possible. For fine adjustments, internal resistor Rᵢₙₜ 504 may also be stepped in value. The specified voltage value (0V value in this embodiment) of (OUT-OUTb) may then become the optimal value for high dynamic range to the input of the data converter (e.g. VTF converter).

### EMI Susceptibilitv

For a very narrow band filter at OUT and OUTb (e.g. ˜400 Hz), when the detected signals at OUT and OUTb (which are indicative of the capacitance, or more specifically a change in capacitance at PAD 510) are at a DC level, all other signals coupled onto PAD 510 may be heavily attenuated. Only those signals that are within a specified frequency value (e.g. ˜4 kHz in some embodiments) of the frequency f₀ of oscillator 514 may fall in band at OUT and OUTb. In addition, any signal that falls in-band may be further integrated by data converter 532 (or the VTF converter, e.g. as shown in FIG. 10). To further reduce the susceptibility for in-band signals, oscillator 514 may be frequency hopped using specified frequency steps (e.g. ˜1 kHz steps in certain embodiments) so that any in-band signal may only be in-band 1/N of the conversion time, where N is the number of frequency steps.

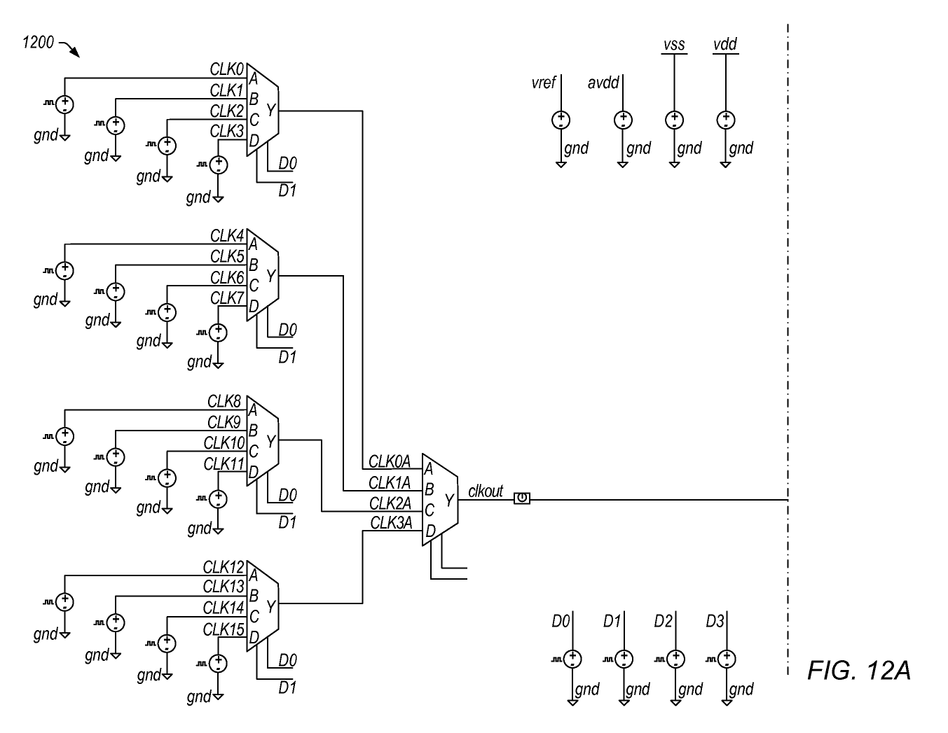

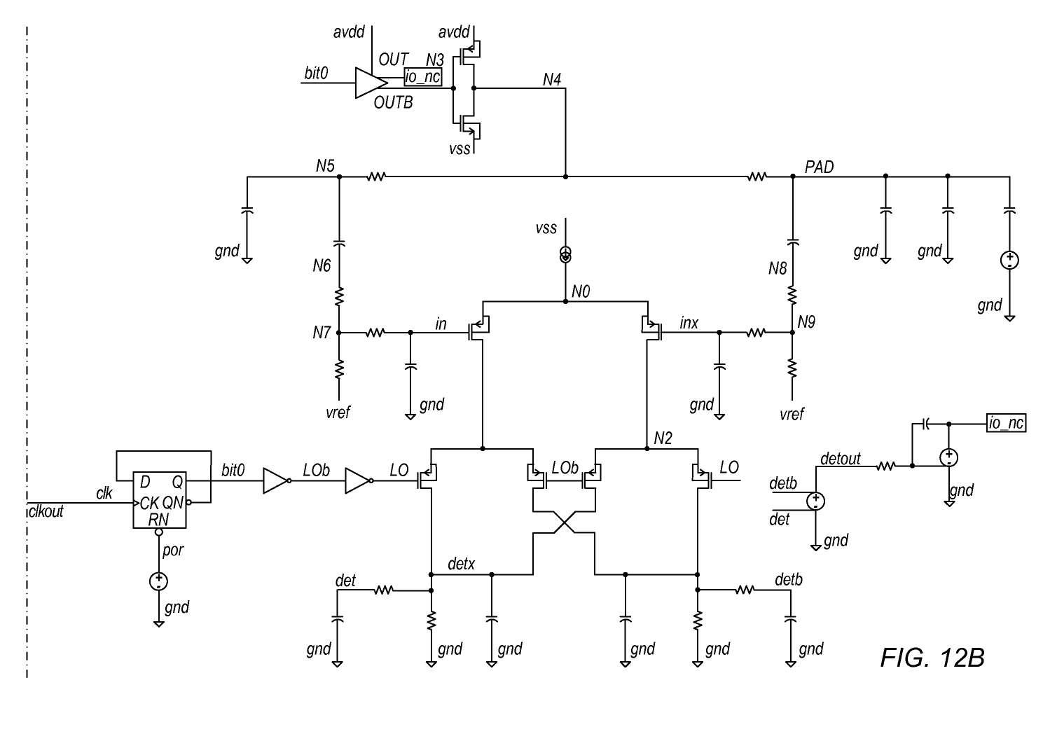

FIG. 12 shows one circuit embodiment of a capacitive sensing circuit built in accordance with the capacitive sensor apparatus shown in FIG. 5. Although the embodiments above have been described in considerable detail, other versions are possible. Numerous variations and modifications will become apparent to those skilled in the art once the above disclosure is fully appreciated. It is intended that the following claims be interpreted to embrace all such variations and modifications. Note the section headings used herein are for organizational purposes only and are not meant to limit the description provided herein or the claims attached hereto.

We claim:

1. A sensing apparatus comprising:
a first load component configured to couple to an interface device having a specific electrical characteristic, wherein the first load component and the specific electrical characteristic of the interface device together form a first load;
a sensing signal-path comprising the first load component, wherein the sensing signal-path is configured to be driven by a periodic control signal having a specific frequency to obtain an input signal;
a reference signal-path comprising a second load that forms a pole commensurate with a pole formed by the first load, wherein the reference signal-path is configured to be driven by the control signal to obtain a reference signal;
a mixer configured to:
generate a difference signal representative of a difference of the input signal and the reference signal; and
correlate the difference signal to the control signal to obtain a main output signal;
wherein the main output signal is indicative of a change in value of the specific electrical characteristic of the interface device.

2. The sensing apparatus of claim 1, wherein the interface device is a sensing pad, and the specific electrical characteristic is a parasitic capacitance corresponding to the sensing pad.

3. The sensing apparatus of claim 2, wherein the change in value of the parasitic capacitance corresponding to the sensing pad is effected by one or more of:
an object coming near the sensing pad; or
an object touching the sensing pad.

4. The sensing apparatus of claim 3, wherein the object is a human finger.

5. The sensing apparatus of claim 2, wherein the first load component is a first resistor, and the second load comprises a second resistor and a capacitor.

6. The sensing apparatus of claim 1, wherein the sensing signal-path and the reference signal-path each comprise a respective buffer configured to be driven by the control signal, wherein the input signal is based on an output of the respective buffer in the sensing signal-path, and the reference signal is based on an output of the respective buffer in the reference signal-path.

7. The sensing apparatus of claim 1, wherein the sensing signal-path and the reference signal-path each comprise a respective band-pass filter;
wherein the respective band-bass filter in the sensing signal-path is driven by an output from the interface device, and wherein the input signal is based on an output of the respective band-bass filter in the sensing signal-path; and
wherein the reference signal is based on an output of the respective band-bass filter in the reference signal-path.

8. The sensing apparatus of claim 7, wherein the respective band-pass filters are identical.

9. The sensing apparatus of claim 7, wherein the respective band-pass filters are configured to attenuate their respective input signals such that respective levels of the input signal and the reference signal are within a dynamic range of the mixer.

10. The sensing apparatus of claim 1, further comprising an oscillator configured to generate the control signal, and provide the control signal and a complement of the control signal to the mixer.

11. The sensing apparatus of claim 10, wherein the oscillator is further configured to provide quadrature signals to the mixer.

12. The sensing apparatus of claim 10, wherein the oscillator is configured to be stepped in frequency in specified increments to minimize effects of electromagnetic interference (EMI) signals on the interface device.

13. The sensing apparatus of claim 10, wherein the oscillator has a 50% duty-cycle.

14. The sensing apparatus of claim 1, further comprising a data converter configured to generate a numeric value based on the main output signal.

15. The sensing apparatus of claim 14, further comprising an amplifier configured to receive the main output signal and provide a gained up version of the main output signal to the data converter to match a dynamic range of the data converter.

16. The sensing apparatus of claim 15, wherein the data converter comprises:
a voltage-to-frequency (VTF) converter configured to generate a VTF output signal based on the gained up version of the main output signal;
a first counter configured to count a first number of cycles of the VTF output signal, and assert an enable signal for the duration of the first number of cycles; and
a second counter configured to count a second number of cycles of a system clock while the enable signal is asserted, and generate a numeric value representative of the second number of cycles.

17. The sensing apparatus of claim 14, wherein the data converter is one of:
an analog-to-digital converter (ADC);
an integrating ADC;
a serial approximation register (SAR); or
a flash converter.

18. The sensing apparatus of claim 1, wherein the first load component, and at least one component of the second load are adjustable to match the first load to the second load for a default value of the specific electrical characteristic of the interface device, to calibrate the sensing apparatus.

19. The sensing apparatus of claim 1, further comprising a capacitor configured to be switchably coupled between reference ground and a common node of the first load component and the sensing device, to match the first load to the second load for a default value of the specific electrical characteristic of the interface device, to calibrate the sensing apparatus;
wherein the first load component, the specific electrical characteristic of the interface device, and the capacitor together form the first load when the capacitor is coupled between reference ground and the common node of the first load component and the sensing device.

20. The sensing apparatus of claim 1, wherein the sensing apparatus is configured on an integrated circuit.

21. A method comprising:
driving a signal sensing-path with a periodic control signal having a specific frequency to generate an input signal, wherein the signal sensing-path comprises an interface device having a specific electrical characteristic;
driving a reference sensing-path with the control signal to generate a reference signal;
generating a difference signal representative of a difference of the input signal and the reference signal; and
correlating the difference signal to the control signal to generate a main output signal, wherein the output signal is indicative of a change in value of the specific electrical characteristic of the interface device.

22. The method of claim 21, wherein the signal sensing-path further comprises a first load component coupled to the interface device;
the method further comprising adjusting a value of the first load component until the main output signal reaches a value of approximately zero for a default value of the specific electrical characteristic of the interface device.

23. The method of claim 22, wherein the reference sensing-path comprises a second load component;
the method further comprising adjusting a value of the second load component until the main output signal reaches a value of approximately zero for a default value of the specific electrical characteristic of the interface device.

24. The method of claim 23, wherein said adjusting a value of the first load component and said adjusting a value of the second load component are performed concurrently.

25. The method of claim 21, wherein said correlating comprises one or more of:
correlating the difference signal to a zero phase shift version of the control signal to detect an amplitude difference induced component of the input signal; or
correlating the difference signal to a −90 degree phase shifted version of the control signal to detect a phase induced component of the input signal;
wherein the amplitude difference induced component of the input signal and the phase induced component of the input signal are a result of a change in the value of the specific electrical characteristic of the interface device.

26. The method of claim 21, further comprising bringing an object near the interface device to effect the change in the value of the specific electrical characteristic of the interface device.

27. The method of claim 26, wherein the object is a human finger.

28. The method of claim 21, further comprising converting the main output signal to a numeric value.

29. The method of claim 28, further comprising filtering the main output signal according to a conversion time elapsed during said converting to optimize a signal to noise ratio (SNR) of the main output signal.

30. The method of claim 28, wherein said converting the main output signal to a numeric value comprises amplifying the main output signal and converting the amplified main output signal to the numeric value.

31. The method of claim 28, further comprising:
performing said converting a plurality of times to obtain a plurality of numeric values; and
setting a flag to indicate that an object has come into the proximity of the interface device, when a difference between any two consecutive ones of the plurality of numeric values exceeds a specified value.

32. A circuit comprising:
a sensing signal-path comprising a first resistor configured to couple to a button pad having a parasitic capacitance that changes when an object is brought within at least a specified distance of the button pad;
a reference signal-path comprising a second resistor coupled to a first capacitor;
an oscillator configured to:
generate a switching signal having a specific frequency;
apply the switching signal to the sensing signal-path to obtain an input signal;
apply the switching signal to the reference signal-path to obtain a reference signal; and
a mixer configured to:
generate a difference signal representative of a difference of the input signal and the reference signal; and
correlate the difference signal to the switching signal to obtain a main output signal;
wherein the main output signal is indicative of a change in the parasitic capacitance of the button pad.

33. The circuit of claim 32, further comprising a data converter configured to generate a numeric value representative of the main output signal.

34. The circuit of claim 33, further comprising an amplifier configured to amplify the main output signal to produce an amplified main output signal having a value within a dynamic range of the data converter, wherein the data converter is configured to generate the numeric value from the amplified main output signal.

35. The circuit of claim 32, further comprising a low-pass filter configured to filter the main output signal to attenuate electromagnetic interference (EMI) signals coupling to the button pad.

36. The circuit of claim 32, further comprising the button pad.
